(19) United States
(12) Patent Application Publication
(10) Pub. No.: US 2025/0327735 A1
(43) Pub. Date: Oct. 23, 2025

(54) Printed Circuit Board Creep Corrosion Sensor and Sensing Method

(71) Applicant: Ciena Corporation, Hanover, MD (US)

(72) Inventor: Khalil Zeaiter, Ottawa (CA)

(21) Appl. No.: 18/641,938

(22) Filed: Apr. 22, 2024

(51) Int. Cl. G01N 17/04; G01N 17/00; H05K 1/02

(52) U.S. Cl. CPC G01N 17/043; G01N 17/006; H05K 1/0268; H05K 2201/0761; H05K 2201/10151

(57) ABSTRACT

A creep corrosion sensor and sensing method including and utilizing: a central pad electrode disposed on a first surface of a printed circuit board (PCB or PCBA); an outer ring electrode disposed concentrically around the central pad electrode on the first surface of the PCB; where the central pad electrode and the outer ring electrode define a creep corrosion area therebetween on the first surface of the PCB; and resistance monitoring means electrically coupled to the central pad electrode and the outer ring electrode and adapted to measure a resistance of the creep corrosion area as affected by creep corrosion present in the creep corrosion area. In an embodiment, a plurality of creep corrosion sensors having varying creep corrosion area gap widths are utilized in a creep corrosion sensor coupon assembly on the PCB to determine an estimated time-to-failure of a component or product utilizing the PCBA.

### TECHNICAL FIELD

The present disclosure relates generally to the fields of electronics and electrical circuits. More particularly, the present disclosure relates to a printed circuit board (PCB) creep corrosion sensor and sensing method.

### BACKGROUND

The typical PCB surface finish for lead (Pb)-free solder and the like is immersion silver (ImAg). ImAg is a coating applied to the copper (Cu) on a PCB, involving the immersion of the PCB in a solution containing silver (Ag) ions that are reduced to elemental Ag on the surface of the Cu. Disadvantageously, ImAg is prone to creep corrosion in harsh corrosive environments, such as the polluted environments containing sulfur(S)-bearing gases in some geographical locations. Such creep corrosion can cause short circuits between the Cu pads and component pins of the PCB and open circuits on thick-film resistors and inductors, for example.

As a result, corrosion sensors are sometimes disposed on the surface of a PCB and monitored in such corrosive environments. These corrosion sensors typically include a quartz crystal microbalance (QCM) or the like that measures the resonance frequency shift with the mass change of the Cu/Ag layer associated with corrosion or utilize meander traces printed on the surface of a PCB that are used to monitor electrical resistance changes in the corrosive environment. Other corrosion sensing methodologies utilize electrochemical impedance spectroscopy, electrochemical noise monitoring, radio-frequency identification (RFID) sensors, fiber optic corrosion sensors, and respirometry.

However, these conventional corrosion sensing methodologies generally fail to adequately reproduce or estimate the creep corrosion distance found in printed circuit board (PCBA) field failures, and thus fail to adequately predict time-to-failure, for example.

The present background is provided as environmental context only. It will be readily apparent to those of ordinary skill in the art that the principles and concepts of the present disclosure may be implemented in other environmental contexts equally, without limitation.

### BRIEF SUMMARY

The present disclosure provides a creep corrosion sensor that measures creep corrosion distance over time at the surface of a PCB or PCBA (collectively a PCB) by measuring insulation resistance between a central pad electrode and an outer ring electrode. These electrodes may be manufactured from ImAg (Cu/Ag) or another metal, metallic material, or conductive material that mimic the field PCBA. Thus, the creep corrosion sensor of the present disclosure exploits, but is not limited to, the galvanic corrosion principles between Cu and Ag, for example. The creep corrosion sensor coupon assembly may utilize a range of electrode gaps, for example from 25 microns to 1,000 microns, with resistance readings over time logged. The cumulative time to reach a predetermined threshold in resistance change can provide creep corrosion distance as a function of time. A linear extrapolation model can be applied to forecast creep corrosion distance and estimate the remaining time-to-failure in a field application. The outer ring electrode and central pad electrode of the present disclosure provide a higher density of exposed Cu area, for example, than linear arrangements. When used, the creep corrosion sensor of the present disclosure can be used to provide a life prediction for a telecommunications product deployed in a harsh corrosive environment, for example.

In one embodiment, the present disclosure provides a creep corrosion sensor including: a central pad electrode disposed on a first surface of a PCB; an outer ring electrode disposed concentrically around the central pad electrode on the first surface of the PCB; where the central pad electrode and the outer ring electrode define a creep corrosion area therebetween on the first surface of the PCB; and resistance monitoring means electrically coupled to the central pad electrode and the outer ring electrode and adapted to measure a resistance of the creep corrosion area as affected by creep corrosion present in the creep corrosion area. The creep corrosion sensor also includes a voltage source electrically coupled to the central pad electrode and the outer ring electrode. In an embodiment, the creep corrosion sensor further includes: a contact pad disposed on a second surface of the PCB opposite the first surface of the PCB; and a via coupling the central pad electrode to the contact pad through the PCB; where one or more of the resistance monitoring means and the voltage source are electrically coupled to one or more of the central pad electrode and the outer ring electrode through the contact pad and the via. One or more of the central pad electrode, the outer ring electrode, the creep corrosion area, the contact pad, and the via are manufactured from a metal, a metallic material, or a conductive material. For example, one or more of the central pad electrode, the outer ring electrode, the creep corrosion area, the contact pad, and the via are manufactured from one or more of ImAg, Cu, Ag, or another metal or metallic material. In an embodiment, the central pad electrode has a circular shape. In an embodiment, the outer ring electrode also has a circular shape and is disposed concentrically and symmetrically around the central pad electrode. The resistance monitoring means are adapted to or coupled to a system adapted to correlate the resistance of the creep corrosion area as affected by the creep corrosion present in the creep corrosion area to an estimated time-to-failure of a component or product utilizing the PCB.

In another embodiment, the present disclosure provides a creep corrosion sensor coupon assembly including a plurality of creep corrosion sensor assemblies each including: a central pad electrode disposed on a first surface of a PCB; and an outer ring electrode disposed concentrically around the central pad electrode on the first surface of the PCB; where the central pad electrode and the outer ring electrode define a creep corrosion area therebetween on the first surface of the PCB. The plurality of creep corrosion sensor assemblies utilize a plurality of different gap widths of the creep corrosion areas. The creep corrosion sensor coupon assembly also includes resistance monitor electronics electrically coupled to each of the plurality of creep corrosion sensor assemblies and adapted to measure a resistance of each of the creep corrosion areas as affected by creep corrosion present in each of the creep corrosion areas. The resistance monitor electronics are adapted to or coupled to a system adapted to correlate the resistance of each of the creep corrosion areas to an estimated time-to-failure of a component or product utilizing the printed circuit board. The creep corrosion sensor coupon assembly further includes a memory coupled to the resistance monitor electronics and adapted to store a measured resistance of each of the creep corrosion areas. In an embodiment, the creep corrosion sensor coupon assembly further includes a network communication link coupled to the resistance monitor electronics and adapted to communicate a measured resistance of each of the creep corrosion areas to a central office network. The creep corrosion sensor coupon assembly further includes a voltage source electrically coupled to each of the plurality of creep corrosion sensor assemblies. In an embodiment, the central pad electrode has a circular shape. In an embodiment, the outer ring electrode also has a circular shape and is disposed concentrically and symmetrically around the central pad electrode.

In a further embodiment, the present disclosure provides a creep corrosion sensing method including providing a plurality of creep corrosion sensor assemblies each including: a central pad electrode disposed on a first surface of a PCB; and an outer ring electrode disposed concentrically around the central pad electrode on the first surface of the PCB; where the central pad electrode and the outer ring electrode define a creep corrosion area therebetween on the first surface of the printed circuit board. The plurality of creep corrosion sensor assemblies utilize a plurality of different gap widths of the creep corrosion areas. The creep corrosion sensing method also includes measuring a resistance of each of the creep corrosion areas as affected by creep corrosion present in each of the creep corrosion areas using resistance monitoring means electrically coupled to each of the plurality of creep corrosion sensor assemblies. The creep corrosion sensing method further includes correlating the resistance of each of the creep corrosion areas to an estimated time-to-failure of a component or product utilizing the PCB. In an embodiment, the central pad electrode has a circular shape. In an embodiment, the outer ring electrode has a circular shape and is disposed concentrically and symmetrically around the central pad electrode.

It will be readily apparent to those of ordinary skill in the art that aspects and features of each of the described embodiments may be incorporated, omitted, and/or combined as desired in a given application, without limitation.

### BRIEF DESCRIPTION OF THE DRAWINGS

The present disclosure is illustrated and described with reference to the various drawings, in which like reference numbers are used to denote like assembly components/method steps, as appropriate, and in which:

FIG. 1 illustrates one embodiment of the creep corrosion sensor of the present disclosure;

FIG. 2 also illustrates one embodiment of the creep corrosion sensor of the present disclosure;

FIG. 3 illustrates one embodiment of the creep corrosion sensor coupon assembly of the present disclosure;

FIG. 4 also illustrates one embodiment of the creep corrosion sensor coupon assembly of the present disclosure;

FIG. 5 is an example plot of creep corrosion growth rate predicted using the creep corrosion sensor and creep corrosion sensor coupon assembly of the present disclosure;

FIG. 6 illustrates one embodiment of the creep corrosion sensor system utilized with the creep corrosion sensor or creep corrosion sensor coupon assembly of the present disclosure;

FIG. 7 illustrates one embodiment of the creep corrosion sensing method of the present disclosure; and

FIG. 8 also illustrates one embodiment of the creep corrosion sensing method of the present disclosure.

It will be readily apparent to those of ordinary skill in the art that aspects and features of each of the illustrated embodiments may be incorporated, omitted, and/or combined as desired in a given application, without limitation.

### DETAILED DESCRIPTION

Again, the present disclosure provides a creep corrosion sensor that measures creep corrosion distance over time at the surface of a PCB or PCBA (collectively a PCB) by measuring insulation resistance between a central pad electrode and an outer ring electrode. These electrodes may be manufactured from ImAg (Cu/Ag) or another metal, metallic material, or conductive material that mimic the field PCBA. Thus, the creep corrosion sensor of the present disclosure exploits, but is not limited to, the galvanic corrosion principles between Cu and Ag, for example. The creep corrosion sensor coupon assembly may utilize a range of electrode gaps, for example from 25 microns to 1,000 microns, with resistance readings over time logged. The cumulative time to reach a predetermined threshold in resistance change can provide creep corrosion distance as a function of time. A linear extrapolation model can be applied to forecast creep corrosion distance and estimate the remaining time-to-failure in a field application. The outer ring electrode and central pad electrode of the present disclosure provide a higher density of exposed Cu area, for example, than linear arrangements. When used, the creep corrosion sensor of the present disclosure can be used to provide a life prediction for a telecommunications product deployed in a harsh corrosive environment, for example.

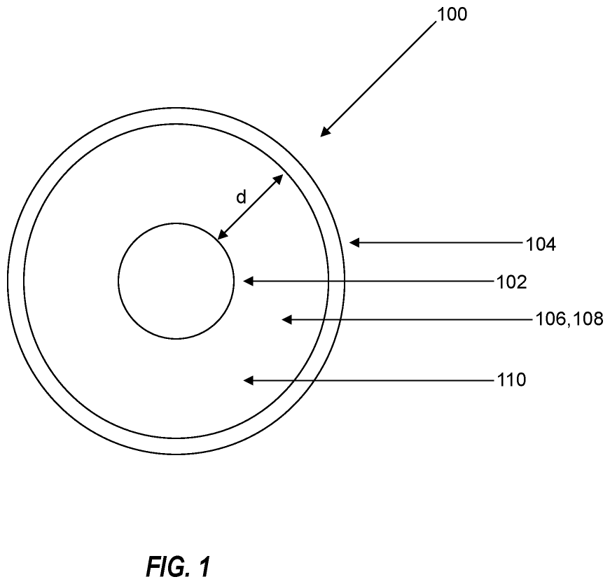

FIG. 1 illustrates one embodiment of the creep corrosion sensor 100 of the present disclosure. The creep corrosion sensor 100 includes a central pad electrode 102 disposed on a first surface 108 of the PCB 110 and an outer ring electrode 104 disposed concentrically around the central pad electrode 102 on the first surface 108 of the PCB 110. Each of the central pad electrode 102 and the outer ring electrode 104 is manufactured from ImAg (Cu/Ag) or another metal, metallic material, or conductive material that may mimic the ImAg (Cu/Ag) or other metal, metallic material, or conductive material disposed on the first surface 108 of the PCB 110. A creep corrosion area 106 is thus defined between the central pad electrode 102 and the outer ring electrode 104 in the metal, metallic material, or conductive material disposed at the first surface 108 of the PCB 110. The creep corrosion distance, d, in any given direction is illustrated. Because the outer ring electrode 104 is circular or otherwise symmetrical and centered around the central pad electrode 102, which may also be circular or otherwise symmetrical, the density of exposed Cu area, for example, is maximized and the creep corrosion sensor 100 is not sensitive to air flow direction across the PCB 110, which can affect the propagation direction of the creep corrosion, making it asymmetrical-a downfall of linear arrangements, for example. In other embodiments, the central pad electrode 102 and/or the outer ring electrode 104 may be a shape other than circular. For example, the central pad electrode 102 and/or the outer ring electrode 104 may be hexagonal or octagonal in shape.

When a voltage (5V, for example) is applied between the central pad electrode 102 and the outer ring electrode 104, the resistance of the creep corrosion area 106 may be measured (by measuring changes in the leakage current across the creep corrosion area 106, for example), which is affected by the creep corrosion present in the ImAg (Cu/Ag) or other metal, metallic material, or conductive material disposed on the first surface 108 of the PCB 110 in the creep corrosion area 106.

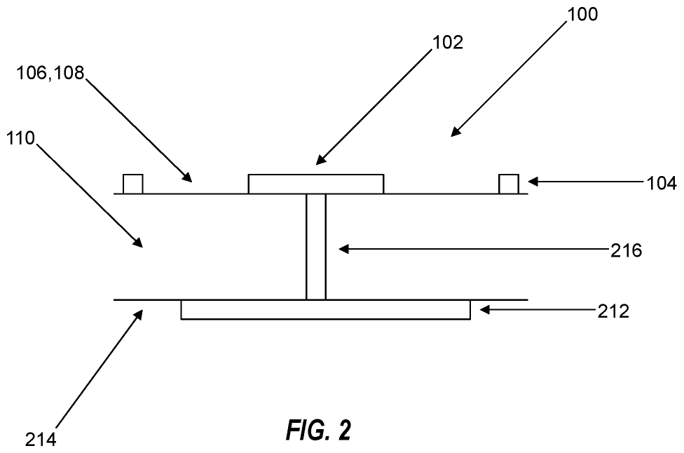

FIG. 2 also illustrates one embodiment of the creep corrosion sensor 100 of the present disclosure. The creep corrosion sensor 100 includes the central pad electrode 102 disposed on the first surface 108 of the PCB 110 and the outer ring electrode 104 disposed concentrically around the central pad electrode 102 on the first surface 108 of the PCB 110. The central pad electrode 102 is coupled to a contact pad 212 disposed on a second surface 214 of the PCB 110 opposite the first surface 108 of the PCB 110. The central pad electrode 102 is coupled to the contact pad 212 by a via 216 running through the PCB 110. The contact pad 212 and the via 216 are each manufactured from Cu or another metal, metallic material, or conductive material. Again, the creep corrosion area 106 is defined between the central pad electrode 102 and the outer ring electrode 104 in the metal, metallic material, or conductive material disposed at the first surface 108 of the PCB 110. Because the outer ring electrode 104 is circular or otherwise symmetrical and centered around the central pad electrode 102, which may also be circular or otherwise symmetrical, the density of exposed Cu area, for example, is maximized and the creep corrosion sensor 100 is not sensitive to air flow direction across the PCB 110.

Electrical contacts to the central pad electrode 102 are made at the contact pad 212 on the second surface 214 of the PCB 110 and to the outer ring electrode 104 on the first surface 108 of the PCB 110. When the voltage (5V, for example) is applied between the central pad electrode 102 and the outer ring electrode 104, the resistance of the creep corrosion area 106 may be measured (by measuring changes in the leakage current across the creep corrosion area 106, for example), which is affected by the creep corrosion present in the ImAg (Cu/Ag) or other metal, metallic material, or conductive material disposed on the first surface 108 of the PCB 110 in the creep corrosion area 106.

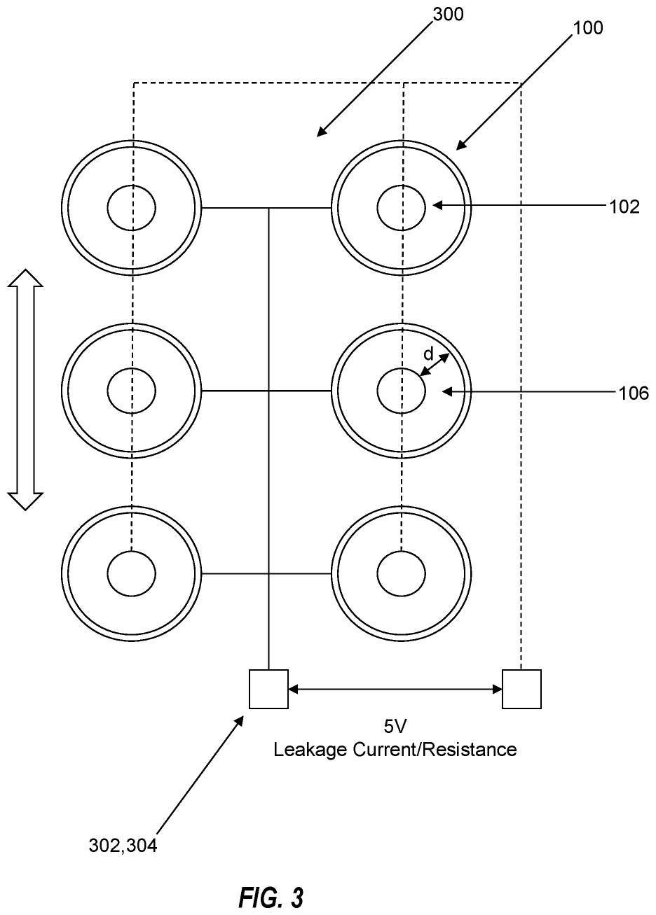

FIG. 3 illustrates one embodiment of the creep corrosion sensor coupon assembly 300 of the present disclosure. The creep corrosion sensor coupon assembly 300 includes a plurality of creep corrosion sensor assemblies 100 arranged in array, for example. Columns or rows of creep corrosion sensor assemblies 100, or individual creep corrosion sensor assemblies 100, may be shifted vertically, horizontally, diagonally, or otherwise in the array to maximize overall exposure to air flow across the array in any given direction. A power supply 302 (5V, for example) and leakage current/resistance probe 304 are coupled to the central pad electrode 102 and outer ring electrode 104 of each of the plurality of creep corrosion sensor assemblies 100, such that the creep corrosion distance, d, can be determined for each of the creep corrosion areas 106, either individually or in the aggregate.

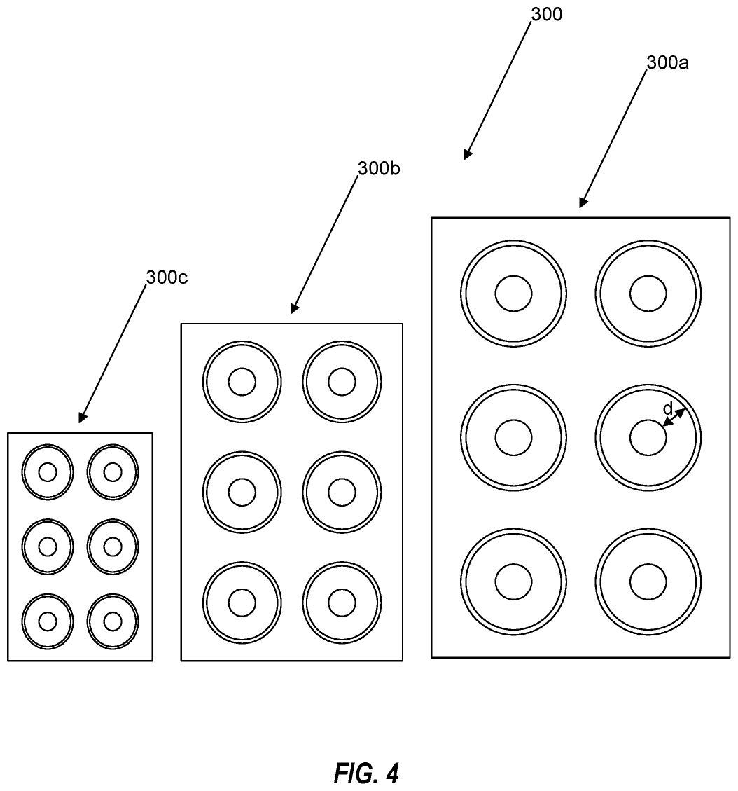

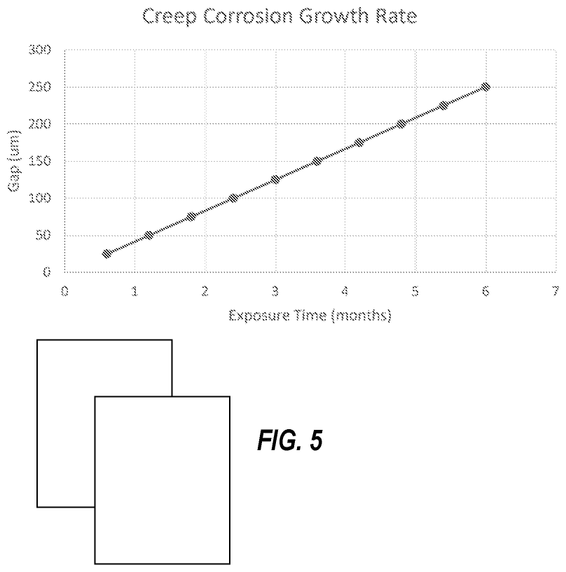

FIG. 4 also illustrates one embodiment of the creep corrosion sensor coupon assembly 300 of the present disclosure. Here, the creep corrosion sensor coupon assembly 300 includes a plurality of creep corrosion sensor arrays 300a, 300b, 300c each utilizing a different creep corrosion electrode gap, for example from 25 microns to 1,000 microns, with resistance readings over time logged. The cumulative time to reach a predetermined threshold in resistance change can provide creep corrosion distance, d, as a function of time. A linear extrapolation model can be applied to forecast creep corrosion distance, d, and estimate the remaining time-to-failure in a field application. An example plot of creep corrosion growth rate is provided in FIG. 5.

The creep corrosion threshold point can be determined from an accelerated test or field creep corrosion data. For example, to survive 10 years, the creep corrosion threshold can be 1 mil (25.4 microns) creep per year for a PCB design of 10 mil (254 microns) as the narrowest gap. Designs with narrow gaps would require a lower threshold.

The creep corrosion sensor 100 can be combined with existing industry practices of defining the corrosion environment class as stated by ISA S71.04-2013, for example, where a sheet of high purity Cu and Ag are used to monitor the creep corrosion growth over a period of 30 days.

The creep corrosion sensor coupon assembly 300 can have a range of gaps from 1 mil to 10 mils, with a step of 1 mil, for example. In a central office environment, the creep corrosion sensor 100 should read resistance R>1 Mega Ohm. As the environment becomes polluted, the lowest gap creep corrosion sensor 100 starts reading lower resistivity. The wider gap creep corrosion sensor 100 would be unchanged since the creep corrosion is progressive over time. The creep corrosion sensor assemblies 100 may be self-calibrated. The measured time of shorting creep corrosion sensor assemblies 100 of different gap distances provides an accurate means to calibrate the sensor corrosion rate.

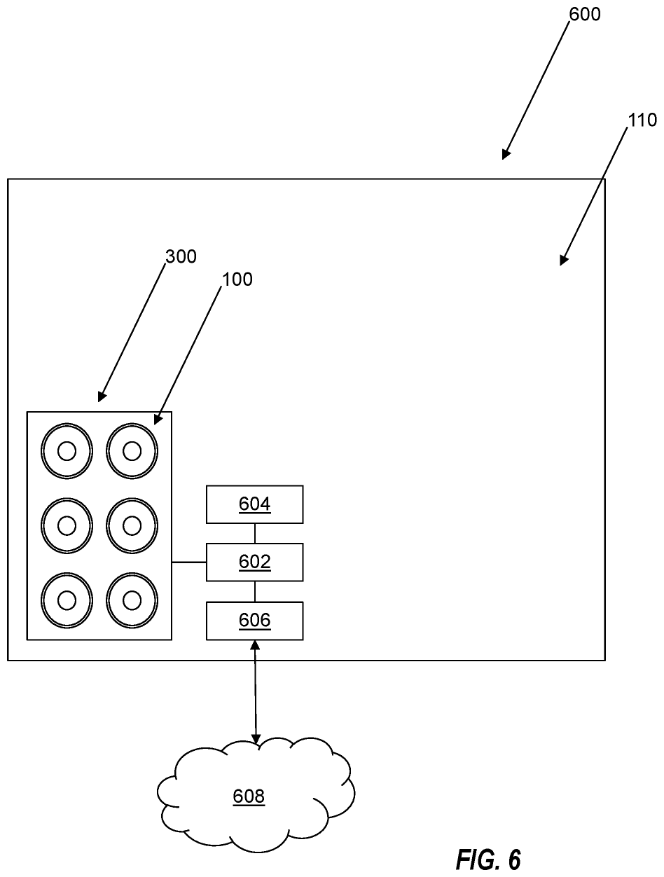

FIG. 6 illustrates one embodiment of the creep corrosion sensor system 600 utilized with the creep corrosion sensor 100 or creep corrosion sensor coupon assembly 300 of the present disclosure. Various such creep corrosion sensor systems are known to those of ordinary skill in the art. The creep corrosion sensor 100 or creep corrosion sensor coupon assembly 300 may be monitored live by attaching on-board resistance monitor electronics 602, as well as a memory chip 604 to read and log the data. For example, a creep corrosion sensor daily reading can be sent through a network communication link 606 to a central office network 608 as part of an overall health check of the deployed system PCB 110 at a customer site. Thus, the creep corrosion sensor 100 can provide an early warning about a pollution issue that, if left untreated, can cause a serious network outage.

Optionally, the sensitivity of the creep corrosion sensor 100 can be improved by adding to the surface of the creep corrosion sensor 100 a catalyst substance, such as organic no-clean flux, a silicon (Si) polymer, or any other substance than can accelerate the corrosion reaction between the pollutant and the metal, metallic, or conductive material of the creep corrosion sensor 100 and the corresponding first surface 108 of the PCB 110.

As mentioned above, conventional corrosion sensing methodologies generally fail to adequately reproduce or estimate the creep corrosion distance found in corroded PCBA failures, and thus fail to adequately predict time-to-failure, for example. These corrosion sensors typically include a QCM or the like that measures the resonance frequency shift with the mass change of the Cu/Ag layer associated with corrosion or utilize meander traces printed on the surface of a PCB that are used to monitor electrical resistance changes in the corrosive environment. Other corrosion sensing methodologies utilize electrochemical impedance spectroscopy, electrochemical noise monitoring, RFID sensors, fiber optic corrosion sensors, and respirometry.

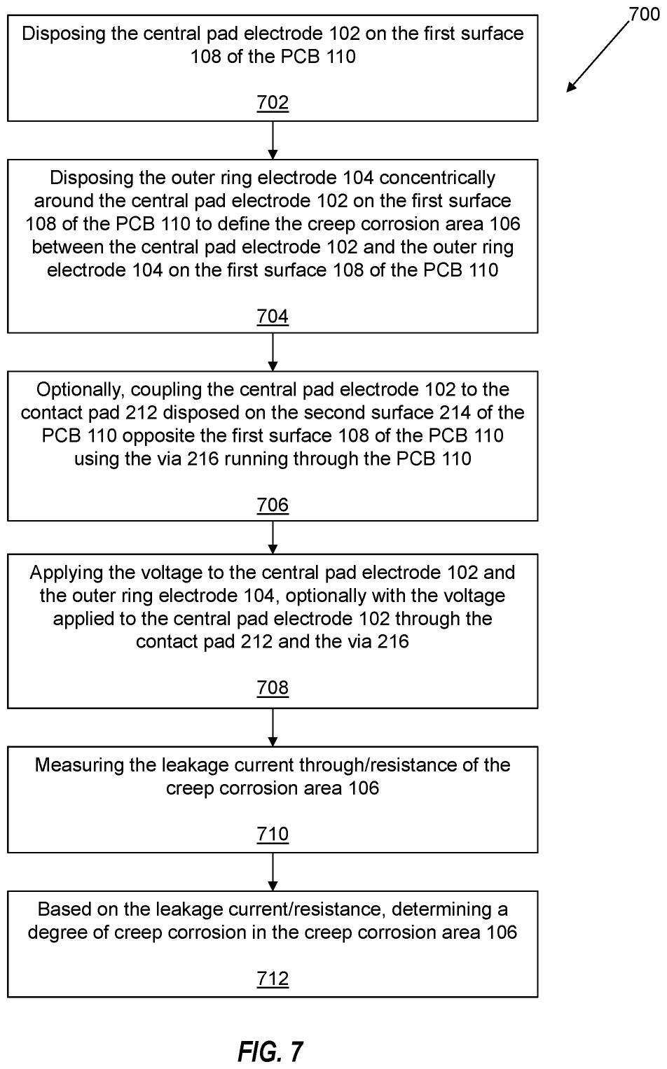

FIG. 7 illustrates one embodiment of the creep corrosion sensing method 700 of the present disclosure. The method 700 includes disposing the central pad electrode 102 on the first surface 108 of the PCB 110 (step 702) and disposing the outer ring electrode 104 concentrically around the central pad electrode 102 on the first surface 108 of the PCB 110 to define the creep corrosion area 106 between the central pad electrode 102 and the outer ring electrode 104 on the first surface 108 of the PCB 110 (step 704). Optionally, the method 700 includes coupling the central pad electrode 102 to the contact pad 212 disposed on the second surface 214 of the PCB 110 opposite the first surface 108 of the PCB 110 using the via 216 running through the PCB 110 (step 706). The method 700 also includes applying the voltage to the central pad electrode 102 and the outer ring electrode 104, optionally with the voltage applied only during reading periods to the central pad electrode 102 through the contact pad 212 and the via 216 (step 708). The method 700 further includes measuring the leakage current through/resistance of the creep corrosion area 106 (step 710). Finally, the method 700 includes, based on the leakage current/resistance, determining a degree of creep corrosion in the creep corrosion area 106 (step 712).

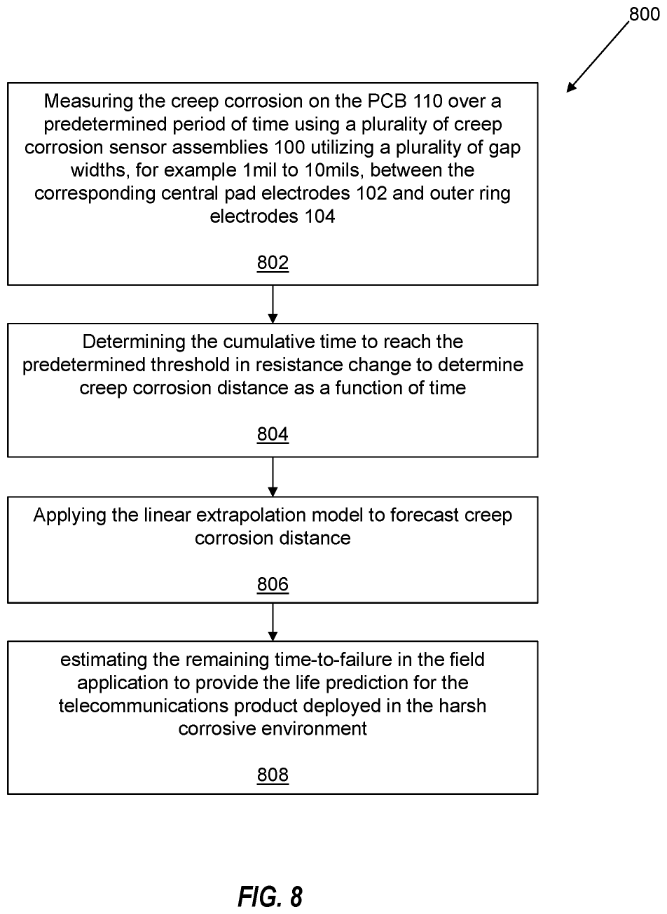

FIG. 8 also illustrates one embodiment of the creep corrosion sensing method 800 of the present disclosure. The method 800 includes measuring the creep corrosion on the PCB 110 over a predetermined period of time using a plurality of creep corrosion sensor assemblies 100 utilizing a plurality of gap widths, for example 1 mil to 10 mils, between the corresponding central pad electrodes 102 and outer ring electrodes 104 (step 802). The method 800 also includes determining the cumulative time to reach the predetermined threshold in resistance change to determine creep corrosion distance as a function of time (step 804). The method 800 further includes applying the linear extrapolation model to forecast creep corrosion distance (step 806). Finally, the method 800 includes estimating the remaining time-to-failure in the field application to provide the life prediction for the telecommunications product deployed in the harsh corrosive environment (step 808).

Thus, again, the present disclosure provides a creep corrosion sensor 100 that measures creep corrosion distance over time at the surface of a PCB or PCBA (collectively a PCB) 110 by measuring insulation resistance between a central pad electrode 102 and an outer ring electrode 104. These electrodes 102, 104 may be manufactured from ImAg (Cu/Ag) or another metal, metallic material, or conductive material that mimic the field PCBA 110. Thus, the creep corrosion sensor 100 of the present disclosure exploits, but is not limited to, the galvanic corrosion principles between Cu and Ag, for example. The creep corrosion sensor coupon assembly 300 may utilize a range of electrode gaps, for example from 1 mil to 10 mils, with resistance readings over time logged. The cumulative time to reach a predetermined threshold in resistance change can provide creep corrosion distance as a function of time. A linear extrapolation model can be applied to forecast creep corrosion distance and estimate the remaining time-to-failure in a field application. The outer ring electrode 104 and central pad electrode 102 of the present disclosure provide a higher density of exposed Cu area, for example, than linear arrangements. When used, the creep corrosion sensor 100 of the present disclosure can be used to provide a life prediction for a telecommunications product deployed in a harsh corrosive environment, for example.

Although the present disclosure is illustrated and described with reference to specific embodiments and examples thereof, it will be readily apparent to those of ordinary skill in the art that other embodiments and examples may perform similar functions and/or achieve like results. All such equivalent embodiments and examples are within the spirit and scope of the present disclosure, are contemplated thereby, and are intended to be covered by the following non-limiting claims for all purposes.

What is claimed is:

1. A creep corrosion sensor comprising:
a central pad electrode disposed on a first surface of a printed circuit board;
an outer ring electrode disposed concentrically around the central pad electrode on the first surface of the printed circuit board;
wherein the central pad electrode and the outer ring electrode define a creep corrosion area therebetween on the first surface of the printed circuit board for which resistance is measured as affected by creep corrosion present in the creep corrosion area.

2. The creep corrosion sensor of claim 1, further comprising:
a voltage source electrically coupled to the central pad electrode and the outer ring electrode; and
resistance monitor electronics electrically coupled to the central pad electrode and the outer ring electrode and adapted to measure the resistance of the creep corrosion area.

3. The creep corrosion sensor of claim 2, further comprising:
a contact pad disposed on a second surface of the printed circuit board opposite the first surface of the printed circuit board; and
a via coupling the central pad electrode to the contact pad through the printed circuit board;
wherein one or more of the resistance monitor electronics and the voltage source are electrically coupled to one or more of the central pad electrode and the outer ring electrode through the contact pad and the via.

4. The creep corrosion sensor of claim 3, wherein one or more of the central pad electrode, the outer ring electrode, the creep corrosion area, the contact pad, and the via are manufactured from a metal, a metallic material, or a conductive material.

5. The creep corrosion sensor of claim 4, wherein the one or more of the central pad electrode, the outer ring electrode, the creep corrosion area, the contact pad, and the via are manufactured from one or more of immersion silver, copper, and silver.

6. The creep corrosion sensor of claim 1, wherein the central pad electrode has a circular shape.

7. The creep corrosion sensor of claim 1, wherein the outer ring electrode has a circular shape and is disposed concentrically and symmetrically around the central pad electrode.

8. The creep corrosion sensor of claim 2, wherein the resistance monitor electronics are adapted to or coupled to a system adapted to correlate the resistance of the creep corrosion area as affected by the creep corrosion present in the creep corrosion area to an estimated time-to-failure of a component or product utilizing the printed circuit board.

9. A creep corrosion sensor coupon assembly comprising:
a plurality of creep corrosion sensor assemblies each comprising:
a central pad electrode disposed on a first surface of a printed circuit board; and
an outer ring electrode disposed concentrically around the central pad electrode on the first surface of the printed circuit board;
wherein the central pad electrode and the outer ring electrode define a creep corrosion area therebetween on the first surface of the printed circuit board;
wherein the plurality of creep corrosion sensor assemblies utilize a plurality of different gap widths of the creep corrosion areas.

10. The creep corrosion sensor coupon assembly of claim 9, further comprising resistance monitor electronics electrically coupled to each of the plurality of creep corrosion sensor assemblies and adapted to measure a resistance of each of the creep corrosion areas as affected by creep corrosion present in each of the creep corrosion areas.

11. The creep corrosion sensor coupon assembly of claim 10, wherein the resistance monitor electronics are adapted to or coupled to a system adapted to correlate the resistance of each of the creep corrosion areas to an estimated time-to-failure of a component or product utilizing the printed circuit board.

12. The creep corrosion sensor coupon assembly of claim 10, further comprising a memory coupled to the resistance monitor electronics and adapted to store a measured resistance of each of the creep corrosion areas.

13. The creep corrosion sensor coupon assembly of claim 10, further comprising a network communication link coupled to the resistance monitor electronics and adapted to communicate a measured resistance of each of the creep corrosion areas to a central office network.

14. The creep corrosion sensor coupon assembly of claim 9, further comprising a voltage source electrically coupled to each of the plurality of creep corrosion sensor assemblies.

15. The creep corrosion sensor coupon assembly of claim 9, wherein the central pad electrode has a circular shape.

16. The creep corrosion sensor coupon assembly of claim 9, wherein the outer ring electrode has a circular shape and is disposed concentrically and symmetrically around the central pad electrode.

17. A creep corrosion sensing method comprising:
providing a plurality of creep corrosion sensor assemblies each comprising:
a central pad electrode disposed on a first surface of a printed circuit board; and
an outer ring electrode disposed concentrically around the central pad electrode on the first surface of the printed circuit board;
wherein the central pad electrode and the outer ring electrode define a creep corrosion area therebetween on the first surface of the printed circuit board;
wherein the plurality of creep corrosion sensor assemblies utilize a plurality of different gap widths of the creep corrosion areas; and
measuring a resistance of each of the creep corrosion areas as affected by creep corrosion present in each of the creep corrosion areas.

18. The creep corrosion sensing method of claim 17, further comprising correlating the resistance of each of the creep corrosion areas to an estimated time-to-failure of a component or product utilizing the printed circuit board.

19. The creep corrosion sensing method of claim 17, wherein the central pad electrode has a circular shape.

20. The creep corrosion sensing method of claim 17, wherein the outer ring electrode has a circular shape and is disposed concentrically and symmetrically around the central pad electrode.
